(19) United States
(12) Patent Application Publication
(10) Pub. No.: US 2015/0187998 A1
(43) Pub. Date: Jul. 2, 2015

(54) PACKAGE STRUCTURE AND METHOD FOR MANUFACTURING THE SAME

(71) Applicant: National Chiao Tung University, Hsinchu City (TW)

(72) Inventors: Chien-Chung LIN, Taipei City (TW); Hao-Chung KUO, Hsinchu County (TW); Kuo-Ju CHEN, Hsinchu City (TW); Hau-Vei HAN, Hsinchu City (TW); Hsin-Chu CHEN, Miaoli County (TW)

(73) Assignee: National Chiao Tung University, Hsinchu City (TW)

(21) Appl. No.: 14/265,590

(22) Filed: Apr. 30, 2014

(30) Foreign Application Priority Data
Dec. 30, 2013 (TW) 102148984

(51) Int. Cl. H01L 33/48; H01L 33/56; H01L 33/58; H01L 33/50

(52) U.S. Cl. CPC H01L 33/483; H01L 33/507; H01L 33/56; H01L 33/58; H01L 2933/0041; H01L 2933/005; H01L 2933/0058

(57) ABSTRACT

A package structure applied for method for a solid-state lighting apparatus is disclosed in the present invention and at least comprises a frame, a light emitting member, an encapsulant and a plurality of fluorescent powders. The light emitting member is disposed in the frame. The encapsulant is provided to fill the frame for packing the light emitting member therein, and the fluorescent powders are dispersed in the encapsulant. Furthermore, there is a plurality of scattering particles doped into the encapsulant.

### BACKGROUND OF THE INVENTION

1. Field of the Invention

The present invention relates to a package structure, more particularly to a package structure applied in the solid-state lighting apparatus, which is doped with the nanoparticles to increase the use rate of blue light, in order to raise the light emitting efficiency.

2. Description of the Prior Art

One or more incandescent lamps are used for the typical lighting products. Although the incandescent lamp is cheap, but 90% of its energy is turned into waste heat, only 10% of the energy is used for lighting. The efficiency is pretty low and operation cost is very high. In addition, the service life for the product of incandescent lamp is very short.

As for the fluorescent lamp developed latter, although the efficiency is higher than the incandescent lamp, its material (such as mercury) is hazardous. In addition, the volume of fluorescent lamp light is large and the cost is quite high. It is not suitable to be used in a small space, and its operation is poor under low temperature. Although the service life fluorescent lamp is longer than the incandescent lamp, the cost of fluorescent lamp is higher than incandescent lamp, and need manpower to maintain it.

Therefore, under the continuous advancement of technology, the Solid-State Lighting (SSL) is an innovative lighting technology, which use the light emitting diode (LEDs), the organic light emitting diode (OLED) or the polymer light emitting diode (PLED) to substitute the conventional incandescent lamp or fluorescent lamp.

Wherein, the Light Emitting Diode (LED) utilizes the change of energy gap upon the combination of electron and hole in semiconductor to release energy into light, which is shown in FIG. 1. FIG. 1 illustrates the package structure for a conventional white light emitting diode. In the package structure 1 of this conventional light emitting diode, the light emitting member 10 is disposed on a concave bottom surface of frame 12 with reflection function, and the welding wire 14 is connected to the light emitting member 10. Part of light emitted by the light emitting member 10 will be converted into white light by the fluorescent powders 18 distributed in the encapsulant 16.

Because the advantages of light emitting diode are high luminance, fast response speed, small volume, low pollution, high reliability, and suitable for mass production etc., which make its application becomes wider in the luminance field or consumable electronic product. Its application is not limited to the white light emitting diode, the red, green and blue light emitting diodes are also widely applied in the large-scale signboard, traffic signal lamp, cell phone, scanner, fax machine and illumination device etc.

Based on the abovementioned description, it is known that the light emitting efficiency and luminance demand of light emitting diode will be paid more attention, so the research and development of high luminance light emitting diode will be an important subject of the solid-state lighting application. Thus, the light utilization rate of general light emitting diode is relatively low at present, which is unsatisfactory for luminance.

### SUMMARY OF THE INVENTION

Therefore, the present invention provides a package structure different from the conventional art. There is a plurality of nanoparticles with scattering characteristics doped into the encapsulant to increase the use rate of blue light, so as to raise the light emitting efficiency. Meanwhile, the package structure provided by the present invention can further make uniform distribution of color temperature under different angles, and then improve the light emitting quality.

As the abovementioned description, the package structure provided by the present invention is applied in a solid-state lighting apparatus comprises a frame, a light emitting member, an encapsulant and a plurality of fluorescent powders. Wherein, the light emitting member is disposed in the frame. The encapsulant is provided to fill the frame for packing the light emitting member therein, and the fluorescent powders are disposed in the encapsulant. Furthermore, there is a plurality of scattering particles doped into the encapsulant.

In an embodiment of the present invention, the abovementioned scattering particles are selected from the group consisting of zirconium oxide (ZrO₂) particles, titanium oxide (TiO₂) particles, aluminum oxide (AlO₂) particles and silicon dioxide (SiO₂) particles.

In an embodiment of the present invention, the proportion of the abovementioned scattering particles in the encapsulant is 0% to 5%.

In an embodiment of the present invention, the abovementioned scattering particles are doped in the encapsulant by a spot gluing method.

In an embodiment of the present invention, the material of the abovementioned encapsulant is silicone.

In an embodiment of the present invention, the diameter of the abovementioned scattering particles is 20 nm to 500 nm.

Another purpose of the present invention is to provide the manufacturing method of the abovementioned package structure comprises the following steps: Firstly, provide a frame, and disposing a light emitting member in the frame. Then, mix a plurality of fluorescent powders and the encapsulant, so that the fluorescent powders can disperse in the encapsulant. Fill the encapsulant with fluorescent powders into the frame for packing the light emitting member. Finally, dop a plurality of scattering particles into the encapsulant.

In an embodiment of the present invention, the abovementioned scattering particles are selected from the group consisting of zirconium oxide (ZrO₂) particles, titanium oxide (TiO₂) particles, aluminum oxide (AlO₂) particles and silicon dioxide (SiO₂) particles.

In an embodiment of the present invention, the abovementioned scattering particles are doped in the encapsulant by a spot gluing method.

In an embodiment of the present invention, the proportion of the abovementioned scattering particles in the encapsulant is 0% to 5%.

As the following description, it is able to further understand the features and advantages of the present invention. Upon reading, please refer to FIG. 1 to FIG. 5.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates the cross-sectional view for the package structure of a conventional light emitting diode;

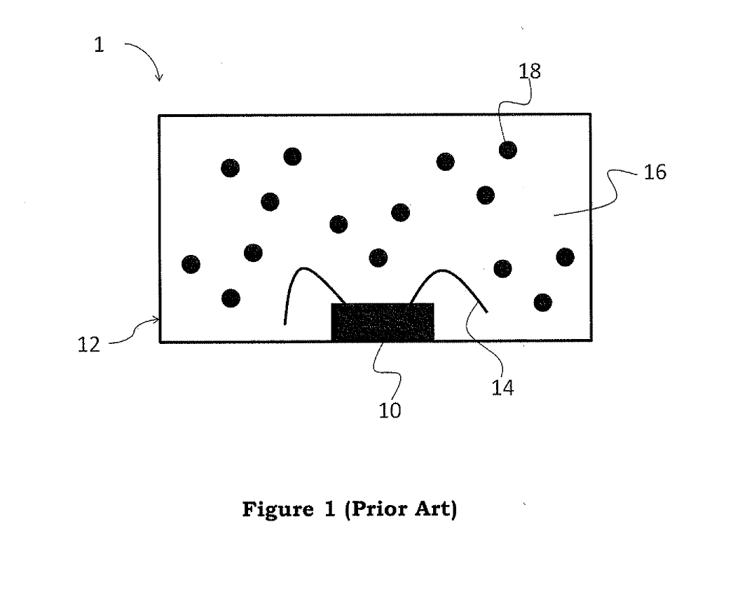

FIG. 2 illustrates the cross-sectional view for the package structure of a light emitting diode according to an embodiment of the present invention;

FIG. 3 illustrates the relation between the zirconium oxide concentration and the lumen efficiency for the package structure of a light emitting diode according to an embodiment of the present invention;

FIG. 4 illustrates the emission spectrum for the package structure of a traditional and present light emitting diode; and

FIG. 5 illustrates the color temperature distribution diagram for the package structure of a light emitting diode doped with different concentration of zirconium oxide.

### DESCRIPTION OF THE PREFERRED EMBODIMENT

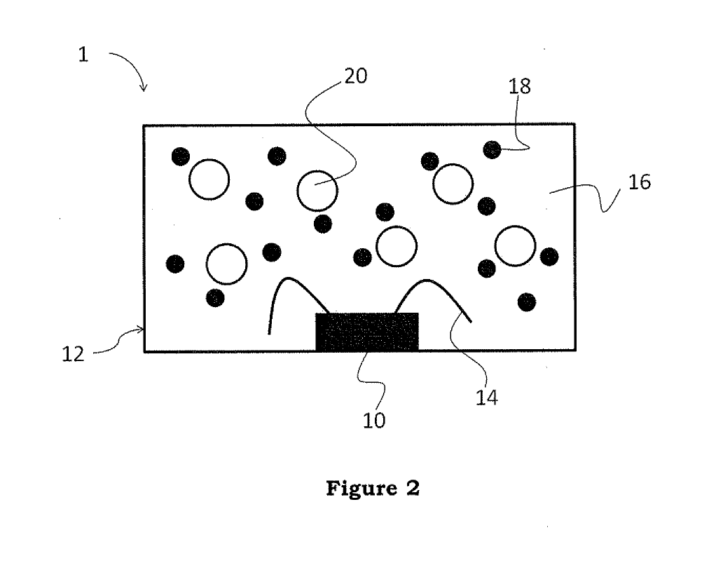

Please refer to FIG. 2. FIG. 2 illustrates the cross-sectional view for the package structure of a light emitting diode according to an embodiment of the present invention. As shown in. FIG. 2, the package structure 1 provided by the present invention comprises a light emitting member 10, a frame 12, two welding wires 14, an encapsulant 16 and a plurality of fluorescent powders 18. The light emitting member is disposed in the frame 12. In a preferred embodiment of the present invention, a light emitting diode is used to describe the light emitting member 10, for example the light emitting member 10 is a blue light emitting diode. However, this package structure also can be used in other optical apparatus, such as the organic light emitting diode, the thin film solar cell or the organic solar cell etc. The present invention is not limited by these applications.

Preferably, in FIG. 2, the light emitting member 10 is disposed on a concave bottom surface of frame 12. Preferably, the light emitting member 10 can be adhered to the concave bottom surface of frame 12 by the silver glue, and electrically connected to the frame 12 by the wire bonding technique. Actually, the connection way between the light emitting member and the frame 12 depends on the number and disposition for the electrodes of the light emitting member 10. The present invention is not limited by these applications.

Then, as shown in FIG. 2, after the setting of light emitting member 10 is finished, the encapsulant 16 can be used to fill the concave place of the frame 12 to encapsulate the light emitting member 10. In a preferred embodiment, the material of the encapsulant 16 may be the transparent polymer or the translucent polymer, such as the soft gel, elastomer or resin, wherein the resin may be the epoxy resin, silicone or epoxy-silicone hybrid resin. Preferably, the encapsulant 16 used in the present invention is the silicone, but it is not limited by this material. In addition, the material of the abovementioned fluorescent powders 18 can be selected from the yellow fluorescent powders, red fluorescent powders, blue fluorescent powders and green fluorescent powders.

It is noted that there is a plurality of scattering particles 20 doped into the encapsulant 16 of the present invention. In a preferred embodiment of the present invention, the abovementioned scattering particles 20 may be selected from the group consisting of zirconium oxide (ZrO₂) nanoparticles, titanium oxide (TiO₂) particles, aluminum oxide (AlO₂) particles or silicon dioxide (SiO₂) particles. Preferably, the diameter of the abovementioned scattering particles 20 is 20 nm to 500 nm, and the refractive index is 2.6, thus it has good scattering effect. In addition, these scattering particles 20 are doped in the encapsulant 16 by a spot gluing method. Furthermore, before manufacturing the package structure of the present invention, the fluorescent powders 18 and the encapsulant 16 can be mixed first, so that fluorescent powders 18 can be dispersed in the encapsulant 16 evenly. Then, the scattering particles 20 are doped in the encapsulant 16 by a spot gluing method. The present invention is not limited by the abovementioned sequence.

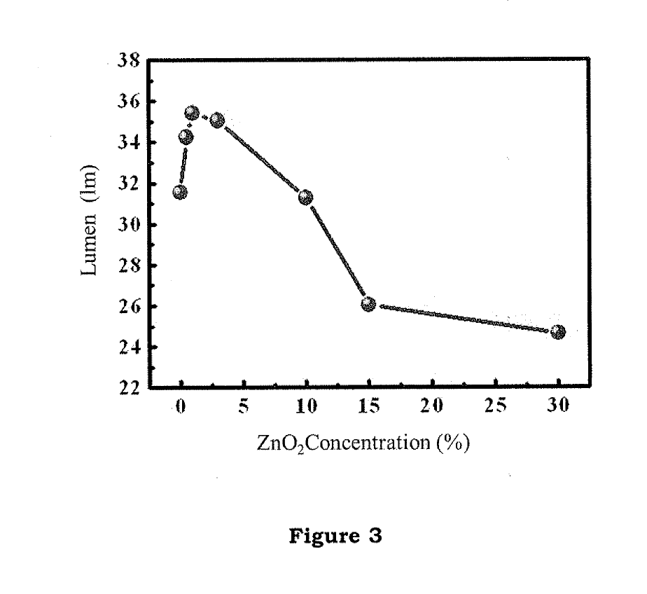

Basically, in FIG. 3 through the scattering feature of nanoparticles, when the scattering particles 20 are doped into the encapsulant 16, it is able to increase the use rate of blue light, in order to raise the light emitting efficiency of optical apparatus adopting said light emitting member. Please refer to FIG. 3 further. FIG. 3 illustrates the relation between the zirconium oxide (ZrO₂) concentration and the lumen efficiency for the package structure of a light emitting diode according to an embodiment of the present invention. As shown in FIG. 3, when the zirconium oxide nanoparticles are not doped into the encapsulant, the lumen efficiency is between 31 lm to 32 lm. However, when the zirconium oxide nanoparticles are doped into the encapsulant, the lumen efficiency is increased to 34 lm to 36 lm. It is proved that when the zirconium oxide nanoparticles with the scattering feature are doped into the encapsulant, the light emitting efficiency can be increased actually.

It is noted that the proportion of the abovementioned scattering particles 20 in the encapsulant is 0% to 5%. As shown in FIG. 3, when the doping amount of zirconium oxide nanoparticles is too high, the lumen efficiency is decreased due to the light emitting routes are influenced by too many nanoparticles.

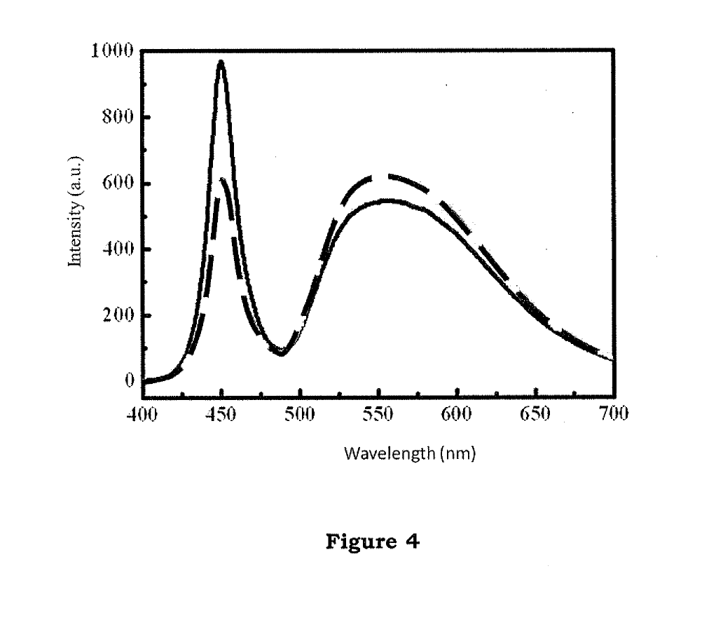

Then, Please refer to FIG. 4. FIG. 4 illustrates the emission spectrum for the package structure of a traditional and present light emitting diode. The solid line represents the emission spectrum for the package structure of traditional light emitting diode, and the dashed line represents the emission spectrum for the package structure of present light emitting diode (in this embodiment, 1% of zirconium oxide nanoparticles is doped into the encapsulant). As shown in FIG. 4, compared to the traditional technique, the intensity of present light emitting diode is significantly reduced at the blue light section of 450 nm to 495 nm, and is increased at the blue light section of 570 nm to 590 nm. It is proved that when the zirconium oxide nanoparticles are doped into the encapsulant, the use rate of blue light can be increased, and the light emitting efficiency can be raised.

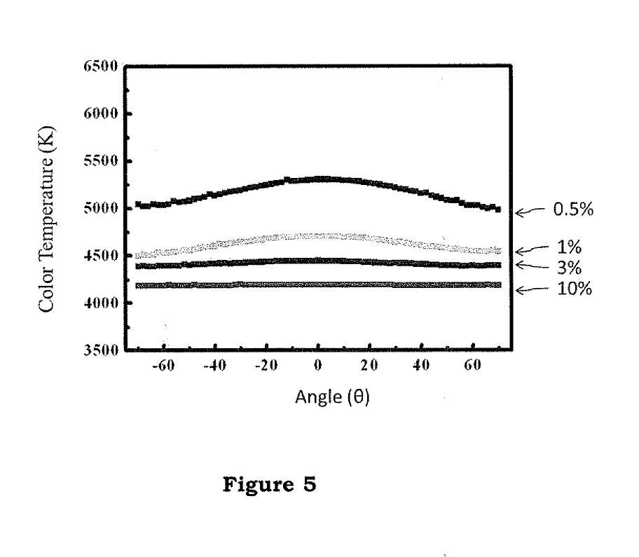

Finally, please refer to FIG. 5. FIG. 5 illustrates the color temperature distribution diagram for the package structure of a light emitting diode doped with different concentration of zirconium oxide. In these curves, the color temperature distribution under different angle is shown for 0.5%, 1%, 3% and 10% of zirconium oxide nanoparticles doped into the encapsulant of package structure, respectively. As shown in FIG. 5, when 0.5% of zirconium oxide nanoparticles are doped into the encapsulant, the color temperature distribution under different angle is between 5000K to 5500K, However, when the doping amount of zirconium oxide nanoparticles is increased to 1%, 3% and 10%, the color temperature distribution under different angle is approaching a straight line. It means when the zirconium oxide nanoparticles are doped into the encapsulant, the color temperature distribution under different angle can be improved, and the light emitting quality can be increased. At this time, it is understood that when the scattering particles (such as the zirconium oxide nanoparticles) are doped into the encapsulant of package structure provided by the present invention, except the lumen efficiency can be increased, the color temperature distribution under different angle can also be improved, and the light emitting quality can be increased. The doping amount of scattering particles (such as the zirconium oxide nanoparticles) can be adjusted in accordance with the abovementioned conditions to obtain an optimal effect.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A package structure applied in a solid-state lighting apparatus, the package structure comprises:
a frame;
a light emitting member, said light emitting member is disposed in said frame;
an encapsulant, said encapsulant is provided to fill said frame for packing said light emitting member; and
a plurality of fluorescent powders, said plurality of fluorescent powders are dispersed in said encapsulant,
wherein, a plurality of scattering particles are doped into said encapsulant.

2. The package structure according to claim 1, wherein said plurality of scattering particles are selected from the group consisting of zirconium oxide (ZrO₂) particles, titanium oxide (TiO₂) particles, aluminum oxide (AlO₂) particles and silicon dioxide (SiO₂) particles.

3. The package structure according to claim 1, wherein a proportion of said plurality of scattering particles in said encapsulant is 0% to 5%.

4. The package structure according to claim 1, wherein said plurality of scattering particles are doped in said encapsulant by a spot gluing method.

5. The package structure according to claim 1, wherein a material of said encapsulant is silicone.

6. The package structure according to claim 1, wherein a diameter of said plurality of scattering particles is 20 nm to 500 nm.

7. A manufacturing method of the package structure, comprises the following steps:
providing a frame;
disposing a light emitting member in said frame;
mixing a plurality of fluorescent powders and said encapsulant, in order to disperse said plurality of fluorescent powders in said encapsulant;
filling said encapsulant with said plurality of fluorescent powders into said frame for packing said light emitting member; and
doping a plurality of scattering particles into said encapsulant.

8. The package structure according to claim 7, wherein said plurality of scattering particles are selected from the group consisting of zirconium oxide (ZrO₂) particles, titanium oxide (TiO₂) particles, aluminum oxide (AlO₂) particles and silicon dioxide (SiO₂) particles.

9. The package structure according to claim 7, wherein said plurality of scattering particles are doped in said encapsulant by a spot gluing method.

10. The package structure according to claim 7, wherein a proportion of said plurality of scattering particles in said encapsulant is 0% to 5%.
